(19) United States
(12) Patent Application Publication
(10) Pub. No.: US 2024/0234403 A1
(43) Pub. Date: Jul. 11, 2024

(54) STACKED MICROELECTRONIC PACKAGES INCLUDING INTERPOSER STRUCTURES AND RELATED METHODS, DEVICES, AND SYSTEMS

(71) Applicant: Micron Technology, Inc., Boise, ID (US)

(72) Inventors: Seng Kim Dalson Ye, Singapore (SG); Kelvin Tan Aik Boo, Singapore (SG); Hong Wan Ng, Singapore (SG); See Hiong Leow, Singapore (SG); Ling Pan, Singapore (SG)

(21) Appl. No.: 18/545,996

(22) Filed: Dec. 19, 2023

Related U.S. Application Data
(60) Provisional application No. 63/479,269, filed on Jan. 10, 2023.

(51) Int. Cl. H01L 25/18; H01L 21/48; H01L 23/498; H01L 25/00; H10B 80/00

(52) U.S. Cl. CPC H01L 25/18; H01L 21/4853; H01L 23/49811; H01L 23/49822; H01L 23/49833; H01L 25/50; H10B 80/00; H01L 24/48

(57) ABSTRACT

A microelectronic device package includes a microelectronic device coupled to a substrate. The microelectronic device package further includes a stack of semiconductor dies positioned over the microelectronic device. The microelectronic device package also includes an interposer positioned between the microelectronic device and the stack of semiconductor dies. The interposer includes a conductive structure electrically connecting the microelectronic device and a ground circuit of the substrate. The interposer further includes an insulative structure positioned between the conductive structure and the stack of semiconductor dies.

### CROSS-REFERENCE TO RELATED APPLICATION

This application claims the benefit under 35 U.S.C. § 119(e) of U.S. Provisional Patent Application Ser. No. 63/479,269, filed Jan. 10, 2023, the disclosure of which is hereby incorporated herein in its entirety by this reference.

### TECHNICAL FIELD

Embodiments of the present disclosure generally relate to stacked microelectronic packages. In particular, embodiments of the present disclosure relate to stacked microelectronic packages including interposer structures and associated methods, devices, and systems.

### BACKGROUND

As a consequence of many factors, including demand for increased portability, computing power, memory capacity and energy efficiency, microelectronic devices such as semiconductor devices and packages comprising such devices, are continuously being reduced in size. The sizes of the constituent features (i.e., critical dimensions) that form the devices, e.g., circuit elements and interconnect lines, as well as the pitch between (i.e., spacing) structures are also constantly being decreased to facilitate this size reduction.

Microelectronic devices may be stacked, such as, in stacked semiconductor packages (e.g., 3-D integrated circuits) to increase one or more of a memory capacity, computing power, etc., of the resulting semiconductor device while still consuming less real estate (i.e., surface area) and facilitating signal speed and integrity. Stacked semiconductor packages may include a plurality of vertically stacked semiconductor dies. The semiconductor dies, in a stacked semiconductor die package, may be operably coupled together by conductive elements between aligned through-silicon vias (TSVs) of superimposed dies, direct contacts, or wire bonding.

A stacked microelectronic device may include different types of semiconductor packages stacked on one another. For example, a stacked semiconductor package, such as a memory stack (e.g., NAND stack) may be stacked over an application specific integrated circuit (e.g., ASIC or controller). The different semiconductor packages may be operatively coupled together through a substrate or through direct connections.

### BRIEF DESCRIPTION OF THE DRAWINGS

While the specification concludes with claims particularly pointing out and distinctly claiming embodiments of the present disclosure, the advantages of embodiments of the disclosure may be more readily ascertained from the following description of embodiments of the disclosure when read in conjunction with the accompanying drawings in which:

FIG. 1 illustrates a cross-sectional view of a microelectronic package in accordance with one or more embodiments of the disclosure;

FIGS. 2 and 3 illustrate enlarged, schematic views of embodiments of an interposer of the microelectronic package illustrated in FIG. 1;

FIG. 4 illustrates a cross-sectional view of a microelectronic package in accordance with one or more embodiments of the disclosure;

FIG. 5 illustrates an enlarged, schematic view of an interposer of the microelectronic package illustrated in FIG. 4;

FIG. 6A illustrates a cross-sectional view of a variation of the embodiment of the microelectronic device package of FIG. 1;

FIG. 6B illustrates a cross-sectional view of a variation of the embodiment of the microelectronic device package of FIG. 4;

FIG. 7A illustrates a cross-sectional view of another variation of the embodiment of the microelectronic device package of FIG. 1;

FIG. 7B illustrates a cross-sectional view of another variation embodiment of the microelectronic device package of FIG. 4;

FIGS. 8 through 10 illustrate cross-sectional views of additional variations of the embodiment of the microelectronic device package of FIG. 1;

FIG. 11 illustrates a flow chart representative of a method of assembly a microelectronic package in accordance with embodiments of the disclosure;

FIG. 12 illustrates a flow chart representative of a method of manufacturing a microelectronic package in accordance with embodiments of the disclosure; and

FIG. 13 is a schematic block diagram of an electronic system in accordance with one or more embodiments of the disclosure.

### DETAILED DESCRIPTION

The following description provides specific details, such as material compositions, shapes, and sizes, in order to provide a thorough description of embodiments of the disclosure. Indeed, the embodiments of the disclosure may be practiced in conjunction with conventional microelectronic device fabrication techniques employed in the industry. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbO₋ₓ₋), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbO₋ₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

Stacked microelectronic devices may include different types of semiconductor packages stacked on one another. For example, a stacked semiconductor package, such as a memory stack (e.g., NAND stack) may be stacked over another microelectronic device or semiconductor die, such as an application specific integrated circuit (ASIC) or a controller. The two different semiconductor packages may have different types of charge building up between them. In some cases, the different charges may result in an electrostatic discharge (ESD) between the two packages. The ESD may damage sensitive circuitry in one or more of the different semiconductor packages by causing shorts or localized heat damage.

Embodiments of the disclosure include positioning an interposer between the two different types of semiconductor packages. The interposer may be configured to electrically isolate the two packages and may further be configured to electrically couple at least one of the two packages to a ground. The features of the interposer may be configured to isolate electrical charges of the two devices and drain electrical charge built up between the two devices. Electrostatic charges may be built up on one or more of the two devices from human handling, machine handling, charging of the devices during testing, among others. Isolating the charges and draining the electrical charge build up may substantially reduce the charge differential (e.g., electrostatic potential or voltage) between the two devices. Reducing the charge differential may substantially prevent ESD between the two devices. Preventing ESD between the devices may improve reliability and yield of the associated devices and packages. Improvements to reliability and yield may reduce the costs of producing the associated devices and packages as well as the associated electronic devices and systems.

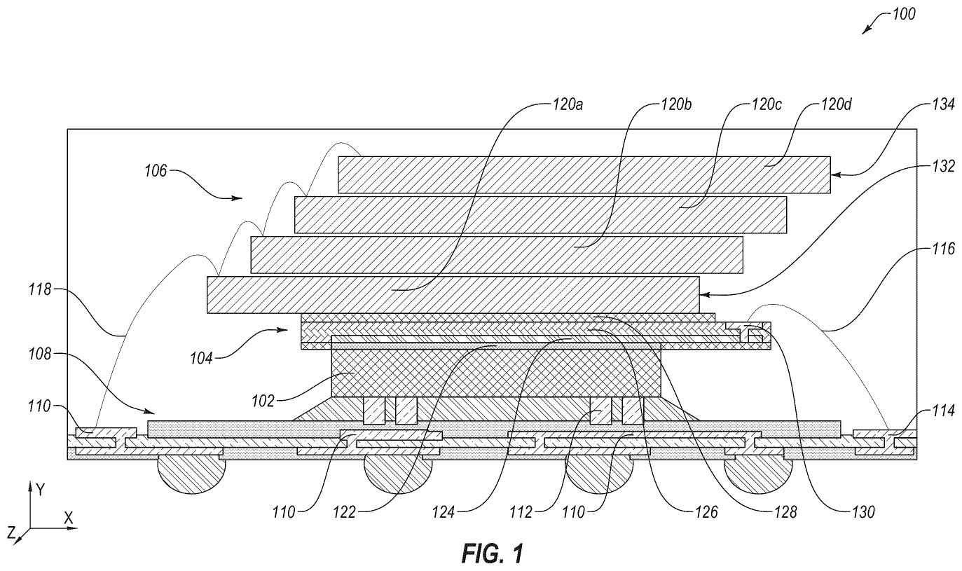

FIG. 1 illustrates a microelectronic device package 100 (e.g., a semiconductor package, microelectronic device, etc.). The microelectronic device package 100 may include a microelectronic device 102 coupled to a substrate 108 and a die stack 106 positioned over the microelectronic device 102. An interposer 104 may be positioned between the microelectronic device 102 and the die stack 106. The interposer 104 may be configured to electrically isolate a bottom surface of a bottom die 120a of the die stack 106 from a top surface of the microelectronic device 102.

The microelectronic device 102 may be electrically coupled to the substrate 108 through one or more direct attachment points 112 (e.g., solder bumps, pins, posts, sockets, pads, etc.) in a direct chip attach (DCA) configuration between a bottom surface of the microelectronic device 102 and conductive pads 110 of the substrate 108. The conductive pads 110 may include ground pads 114, power pads, transmitting pads (c.g., pads configured to transmit data, signals, commands, etc., to the microelectronic device 102), receiving pads (e.g., pads configured to receive data, signals, commands, etc., from the 102), etc. The substrate 108 may be a circuit board, such as a printed circuit board, single sided circuit board, double sided circuit board, multilayer circuit board, etc. The substrate 108 may include multiple horizontal and vertical conductive paths disposed with the substrate 108. The conductive paths may electrically couple one or more conductive pads 110 together. For example, ground pads 114 may be electrically coupled together, and transmitting pads of the microelectronic device 102 may be electrically coupled to receiving pads of other components, such as the die stack 106, a dynamic random-access memory (DRAM) device, etc.

The die stack 106 may be electrically coupled to the substrate 108 through one or more wire bonds 118 coupled between at least one of the dies 120a, 120b, 120c, 120d and at least one of the conductive pads 110 of the substrate 108. For example, wire bonds may extend between the dies 120d, 120c, 120b, 120a to electrically couple the dies 120d, 120c, 120b, 120a of the die stack 106 together and a wire bond 118 may then extend from the bottom die 120a to a conductive pad 110 on the substrate 108 as illustrated in FIG. 1. In another embodiment, a wire bond 118 may extend from each die 120a, 120b, 120c, 120d to the conductive pad 110 on the substrate 108. As described above, the conductive pads 110 may include one or more of a ground pad 114, a power pad, a transmitting pad, and a receiving pad. In some embodiments, the die stack 106 may be operatively coupled to the microelectronic device 102 through the substrate 108. For example, the conductive pads 110 coupled to the die stack 106 through the wire bonds 118 may be operatively coupled to the conductive pads 110 coupled to the microelectronic device 102 through the direct attachment points 112.

The interposer 104 may be formed of multiple structures. For example, the interposer 104 may include a conductive structure 124 and an insulative structure 126. The conductive structure 124 may include a conductive pad 130, which may be configured to electrically couple the conductive structure 124 to a conductive pad 110 in the substrate 108. For example, the conductive pad 130 may be coupled to a ground pad 114 of the substrate 108 through a wire bond 116. The conductive structure 124 may be configured to electrically couple a top surface of the microelectronic device 102 to the ground pad 114. The ground pad 114 may be electrically coupled to a ground (e.g., earth ground, signal ground, etc.) or neutral (e.g., common, neutral, etc.) through the substrate 108. Electrically coupling the top surface of the microelectronic device 102 to the ground pad 114. The conductive structure 124 may be configured to drain an accumulated electrical charge from the surface of the microelectronic device 102 to the ground, which may reduce an electrical potential between the microelectronic device 102 and the die stack 106. The conductive structure 124 may be formed from a conductive material, such as one or more of a metal, an alloy, a conductive metal-containing material, or a conductively doped semiconductor material.

The insulative structure 126 of the interposer 104 may be positioned between the conductive structure 124 and the die stack 106. The insulative structure 126 may be formed from an electrically insulative material, such as dielectric oxide material, a titanium oxide (TiOₓ), a zirconium oxide (ZrOₓ), a tantalum oxide (TaOₓ), and a magnesium oxide (MgOₓ), at least one dielectric nitride material, at least one dielectric oxynitride material, at least one dielectric oxycarbide material, at least one hydrogenated dielectric oxycarbide material, and at least one dielectric carboxynitride material. The insulative structure 126 may be configured to substantially electrically isolate the die stack 106 from the upper surface of the microelectronic device 102.

The conductive structure 124 of the interposer 104 may be attached to the microelectronic device 102 through a conductive connection 122. The conductive connection 122 may be a conductive material configured to secure the interposer 104 to the microelectronic device 102. For example, the conductive connection 122 may be a flowable material, such as solder, or a conductive adhesive, such as a metal paste, conductive tape, conductive epoxy, etc. The conductive connection 122 may secure the conductive structure 124 of the interposer 104 to the upper surface of the microelectronic device 102, while maintaining an electrical connection between the upper surface of the microelectronic device 102 with the conductive structure 124.

The insulative structure 126 of the interposer 104 may be attached to the bottom die 120a of the die stack 106 through a connection 128. The connection 128 may be an insulative material, such as an adhesive or tape. The connection 128 may be configured to secure the die stack 106 to the insulative structure 126 of the interposer 104, while maintaining the electrically insulating properties of the insulative structure 126 relative to the conductive structure 124 and microelectronic device 102.

The interposer 104 may extend beyond a lateral end 132 of the bottom die 120a. The conductive pad 130 may be positioned in the portion of the interposer 104 that is extended beyond the lateral end 132 of the bottom die 120a, such that the wire bond 116 may be coupled to the conductive pad 130 without contacting the bottom die 120a. The interposer 104 may also remain within a footprint defined by the die stack 106. For example, the interposer 104 may not extend beyond a lateral end 134 of a top die 120d of the die stack 106. Thus, the interposer 104 may not add to a lateral dimension or footprint of the microelectronic device package 100.

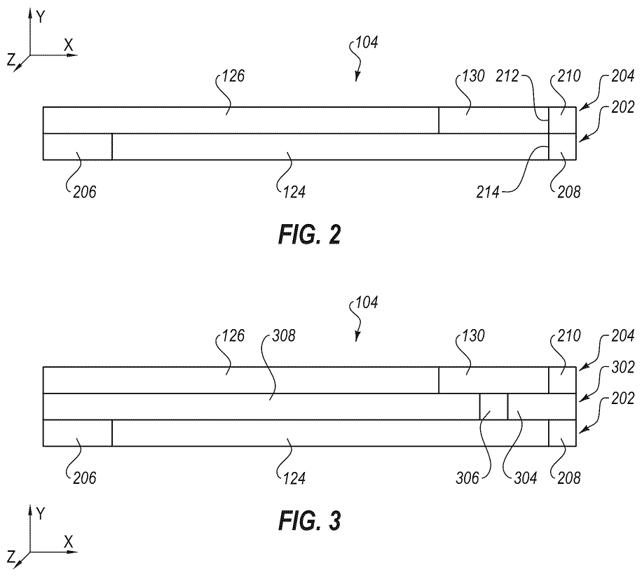

FIG. 2 illustrates an enlarged schematic view of an embodiment of the interposer 104 of the microelectronic device package 100. The interposer 104 may include at least two stacked structures. A device contact structure 202 may be positioned on an end (e.g., top or bottom as illustrated in FIG. 2) of the interposer 104 proximate the microelectronic device 102 (FIG. 1). The device contact structure 202 may include the conductive structure 124 with insulative edge structures 206, 208 bounding the conductive structure 124. The insulative edge structures 206, 208 may be formed from an insulative material, similar to the insulative structure 126. The insulative edge structures 206, 208 may be configured to substantially prevent shorts between the conductive structure 124 and other structures of the microelectronic device package 100 by substantially preventing the conductive structure 124 from contacting other structures of the microelectronic device package 100.

A stack contact structure 204 of the interposer 104 may be positioned on a second end (e.g., bottom or top as illustrated in FIG. 2) of the interposer 104 proximate the die stack 106 (FIG. 1). The stack contact structure 204 may include the insulative structure 126 and the conductive pad 130 with an additional insulative edge 210 on a side of the conductive pad 130 opposite the insulative structure 126. The stack contact structure 204 may be positioned directly on the device contact structure 202. The conductive pad 130 may be positioned over an end of the conductive structure 124, such that an edge 212 of the conductive pad 130 is substantially laterally aligned with an edge 214 of the conductive structure 124. The conductive pad 130 may be in direct contact with the conductive structure 124, such that the conductive pad 130 may be electrically connected to the conductive structure 124. The insulative structure 126 may be positioned over the conductive structure 124, such that the insulative structure 126 may be in direct contact with the conductive structure 124 over each area that is not in direct contact with the conductive pad 130. The insulative structure 126 may cover an area of the interposer 104 that is configured to be attached to the die stack 106 (FIG. 1), such that the insulative structure 126 may be positioned between the conductive structure 124 and the die stack 106 (FIG. 1). The insulative structure 126 may also be positioned between the conductive pad 130 and the die stack 106 (FIG. 1).

FIG. 3 illustrates an enlarged schematic view of another embodiment of the interposer 104 of the microelectronic device package 100. As described above, the interposer 104 may include at least two stacked structures. The device contact structure 202 may be positioned on an end (e.g., top or bottom as illustrated in FIG. 3) of the interposer 104 proximate the microelectronic device 102 (FIG. 1). The device contact structure 202 includes the conductive structure 124 with the insulative edge structures 206, 208 bounding the conductive structure 124. The stack contact structure 204 of the interposer 104 may be positioned on a second end (e.g., bottom or top as illustrated in FIG. 2) of the interposer 104 proximate the die stack 106 (FIG. 1). The stack contact structure 204 includes the insulative structure 126 and the conductive pad 130 with the additional insulative edge 210 on a side of the conductive pad 130 opposite the insulative structure 126.

The interposer 104 may also include intermediate structures 302 positioned between the device contact structure 202 and the stack contact structure 204. The intermediate structures 302 may include an insulative structure 308 and an insulative edge structure 304 substantially surrounding a conductive connecting structure 306. The conductive connecting structure 306 may be positioned between the conductive structure 124 and the conductive pad 130. The conductive connecting structure 306 may be formed of and include conductive material. The conductive connecting structure 306 may be configured to form an electrical connection between the conductive structure 124 and the conductive pad 130. The conductive connecting structure 306 may have a horizontal surface area less than or equal to a horizontal surface area of the conductive pad 130. Thus, the insulative structure 308 may cover an area of the conductive structure 124 equal to or greater than an area of the conductive structure 124 covered by the insulative structure 126. The intermediate structures 302 may increase the insulative properties of the interposer 104 by increasing a thickness of insulative material positioned between the conductive structure 124 and the die stack 106 (FIG. 1).

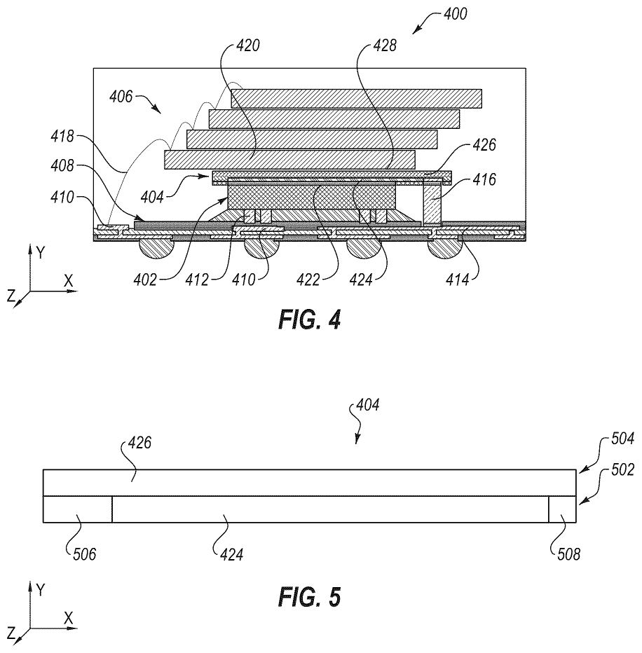

FIG. 4 illustrates a microelectronic device package 400, in accordance with additional embodiments of the disclosure. Similar to the microelectronic device package 100 (FIG. 1), the microelectronic device package 400 may include a microelectronic device 402 and a die stack 406 that are each electrically coupled to a substrate 408. An interposer 404 may be positioned between the microelectronic device 402 and the die stack 406. Each of the microelectronic device 402, the die stack 406, and the interposer 404 may be individually coupled to conductive pads 410 of the substrate 408. The conductive pads 410 may include one or more of a ground pad 414, a power pad, a transmitting pad, and a receiving pad. The microelectronic device 402 may be coupled to one or more conductive pads 410 through direct attachment points 412 (e.g., solder bumps, pins, posts, sockets, pads) in a DCA configuration between a bottom surface of the microelectronic device 402 and the conductive pads 410 of the substrate 408. The die stack 406 may be coupled to one or more of the conductive pads 410 through one or more wire bonds 418 extending between one or more of the dies of the die stack 406 and one or more of the conductive pads 410 of the substrate 408.

The interposer 404 may be coupled to a ground pad 414 of the substrate 408 through a conductive post 416 (which may also be characterized as a pillar, column or stud) extending between a bottom surface of the interposer 404 and the ground pad 414. The interposer 404 may include a conductive structure 424 coupled to the conductive post 416. The conductive structure 424 may also be coupled to a surface of the microelectronic device 402. Thus, the conductive structure 424 may electrically couple the surface of the microelectronic device 402 to the ground pad 414 through the conductive post 416. The electrical connection between the surface of the microelectronic device 402 and the ground pad 414 may drain electrical charges built up on the microelectronic device 402.

The interposer 404 may also include an insulative structure 426 positioned between the conductive structure 424 and a bottom die 420 of the die stack 406. Connecting the conductive post 416 to the conductive structure 424 through a bottom surface of the interposer 404 may facilitate the insulative structure 426 of the interposer 404 extending across an entire upper surface area of the interposer 404 (e.g., such that an upper structure of the interposer 404 is substantially free of conductive material). Extending the insulative structure 426 across the entire upper surface of the interposer 404 may reduce a complexity of a process of forming the interposer 404 and may increase the insulative properties of the interposer 404 between the microelectronic device 402 and the die stack 406.

Because the entire upper surface of the interposer 404 is formed from the insulative structure 426, the interposer 404 may remain within a footprint of the bottom die 420 of the die stack 106. In other embodiments, the interposer 404 may extend beyond a lateral end of the bottom die 420 as illustrated in FIG. 4. A lateral length of the extension of the interposer 404 from the surface of the microelectronic device 402 may be sufficient to reach the conductive post 416 extending between the interposer 404 and the ground pad 414 in the substrate 408.

Similar to the microelectronic device package 100 (FIG. 1), the interposer 404 may be attached to the microelectronic device 402 through a conductive connection 422. The conductive connection 422 may include conductive material configured to secure the interposer 404 to the microelectronic device 402. For example, the conductive connection 422 may be a flowable material, such as solder, or a conductive adhesive, such as a metal paste, conductive tape, conductive epoxy, etc. The interposer 404 may be attached to the bottom die 420 of the die stack 406 through a connection 428 (e.g., adhesive material, tape). The connection 428 may be formed of and include insulative material.

FIG. 5 illustrates an enlarged schematic view of the interposer 404. The interposer 404 may include at least two stacked structures. A device contact structure 502 may be positioned on an end (e.g., top or bottom as illustrated in FIG. 5) of the interposer 404 proximate the microelectronic device 402 (FIG. 4). The device contact structure 502 includes the conductive structure 424 with insulative edge structures 506, 508 bounding the conductive structure 424. The stack contact structure 504 of the interposer 404 may be positioned on a second end (e.g., bottom or top as illustrated in FIG. 4) of the interposer 404 proximate the die stack 406 (FIG. 4). The stack contact structure 504 includes the insulative structure 426. As described above, the insulative structure 426 may define the entire upper surface of the interposer 404, such that the insulative structure 426 may substantially form the entire stack contact structure 504 of the interposer 404.

In some embodiments, the interposer 404 also includes intermediate structures positioned between the device contact structure 502 and the stack contact structure 504. The intermediate structures may include additional insulative structures. The additional insulative structures may have substantially a same size as the insulative structure 426. Thus, the additional intermediate structures may increase the insulative properties of the interposer 404 by increasing a thickness of insulative material positioned between the conductive structure 424 and the die stack 406 (FIG. 4).

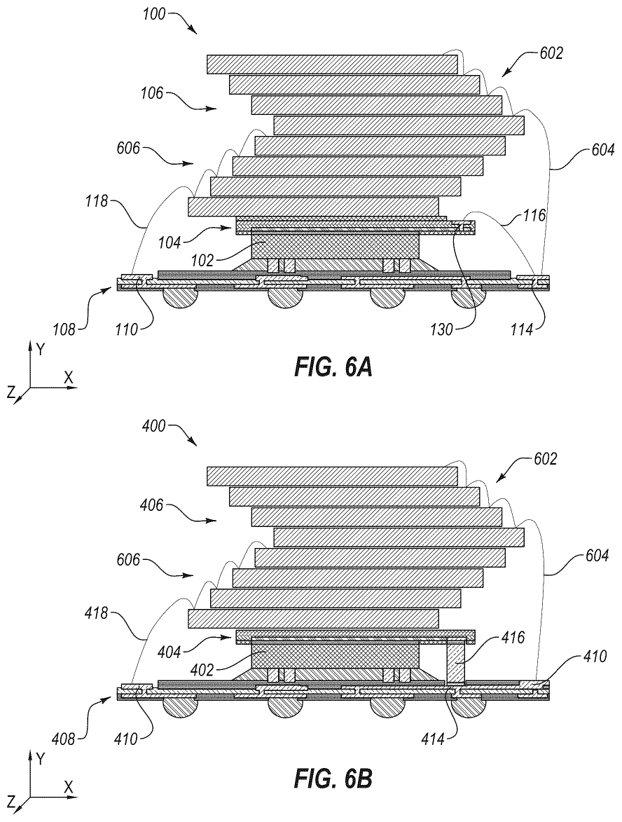

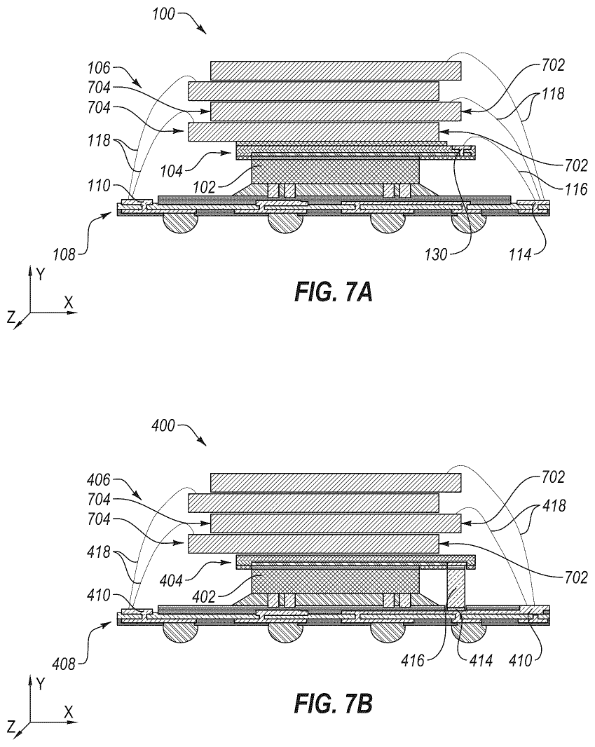

The microelectronic device packages 100, 400 described above may have different configurations of die stacks 106, 406 and microelectronic devices 102, 402. FIGS. 6A-7B illustrate additional example embodiments of the microelectronic device packages 100, 400 including different types of die stacks 106, 406. These embodiments are merely illustrative and non-limiting.

FIG. 6A illustrates the microelectronic device package 100 including all the features of the microelectronic device package 100 of FIG. 1, with an additional reverse shingle die stack 602 positioned over the die stack 106 of FIG. 1. The die stack 106 as illustrated in FIG. 1 is commonly referred to as a shingle stack 606. The shingle stack 606 and the reverse shingle die stack 602 may combine to form a single die stack 106. As illustrated in FIG. 6A, the shingle stack 606 may include wire bonds 118 coupling the shingle stack 606 to a first conductive pad 110 and the reverse shingle die stack 602 may include additional wire bonds 604 coupling the reverse shingle die stack 602 to another conductive pad 110, such as the ground pad 114 as illustrated in FIG. 6A. As described above, in some embodiments the conductive pad 110 on both sides of the microelectronic device package 100 may be ground pads 114, which may each be coupled together through the substrate 108.

In some embodiments, the conductive pad 130 of the interposer 104 is coupled to the same ground pad 114 as one or more of the wire bonds 118, 604 from the die stack 106. In other embodiments, the wire bonds 118, 604 from the die stack 106 are coupled to distinct conductive pads 110 or ground pads 114 from the wire bond 116 of the interposer 104.

FIG. 6B illustrates the microelectronic device package 400 including all the features of the microelectronic device package 400 of FIG. 4, with an additional reverse shingle die stack 602 positioned over the shingle stack 606. The shingle stack 606 and the reverse shingle die stack 602 may combine to form a single die stack 406. As illustrated in FIG. 6B, the shingle stack 606 may include wire bonds 418 coupling the shingle stack 606 to a first conductive pad 410 and the reverse shingle die stack 602 may include additional wire bonds 604 coupling the reverse shingle die stack 602 to another conductive pad 410, as illustrated in FIG. 6B. As described above, in some embodiments the conductive pad 410 on both sides of the microelectronic device package 400 may be ground pads 414, which may each be coupled together through the substrate 408.

In some embodiments, conductive post 416 extending between the interposer 404 and the substrate 408 is coupled to the same ground pad 414 as one or more of the wire bonds 418, 604 from the die stack 406. In other embodiments, the wire bonds 418, 604 from the die stack 406 are coupled to distinct conductive pads 410 or ground pads 414 from the conductive post 416 from the interposer 404, as illustrated in FIG. 6B.

FIG. 7A illustrates the microelectronic device package 100 including all the features of the microelectronic device package 100 of FIG. 1. The die stack 106 may be formed by dies with alternating pad locations as illustrated in FIG. 7A. The dies in the die stack 106 may alternate lateral positions, such that each adjacent die is laterally offset from one another while cach die is positioned in one of two lateral positions. The alternating lateral positions may facilitate a top surface of one of a first lateral end 702 or a second lateral end 704 being exposed, such that a wire bond 118 may be coupled to the associated die. Thus, the wire bonds 118 may extend from opposing lateral ends 702, 704 of adjacent dies. The wire bonds 118 from adjacent dies may also be connected to conductive pads 110 of the substrate 108 on opposing sides of the microelectronic device package 100.

In some embodiments, the conductive pad 130 of the interposer 104 is coupled to the same ground pad 114 as one or more of the wire bonds 118 from the die stack 106. In other embodiments, the wire bonds 118 from the die stack 106 are coupled to distinct conductive pads 110 or ground pads 114 from the wire bond 116 of the interposer 104.

FIG. 7B illustrates the microelectronic device package 400 including all the features of the microelectronic device package 400 of FIG. 4. The die stack 406 may be formed by dies with alternating pad locations as illustrated in FIG. 7B. The dies in the die stack 406 may alternate lateral positions, such that each adjacent die is laterally offset from one another while each die is positioned in one of two lateral positions. The alternating lateral positions may facilitate a top surface of one of a first lateral end 702 or a second lateral end 704 being exposed, such that a wire bond 418 may be coupled to the associated die. Thus, the wire bonds 418 may extend from opposing lateral ends 702, 704 of adjacent dies. The wire bonds 418 from adjacent dies may also be connected to conductive pads 410 of the substrate 408 on opposing sides of the microelectronic device package 400.

In some embodiments, conductive post 416 extending between the interposer 404 and the substrate 408 is coupled to the same ground pad 414 as one or more of the wire bonds 418 from the die stack 406. In other embodiments, the wire bonds 418 from the die stack 406 are coupled to distinct conductive pads 410 or ground pads 414 from the conductive post 416 from the interposer 404, as illustrated in FIG. 7B.

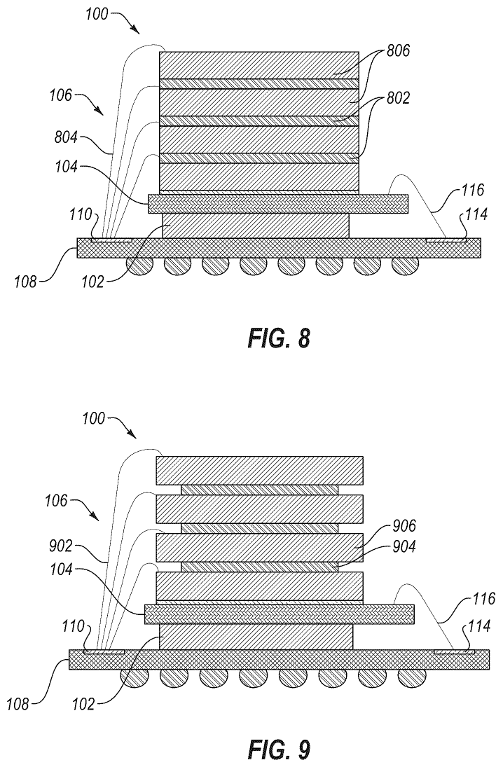

In additional embodiments, the dies of the die stack 106 may be positioned, such that there is substantially no lateral offset between vertically neighboring dies. FIGS. 8 through 10 illustrate different embodiments of die stacks 106 where the adjacent dies are not substantially laterally offset from one another. Each of FIGS. 8 through 10 are illustrated as alternate configurations for the microelectronic device package 100 previously described with reference to FIG. 1, however, it is understood that other types of microelectronic package configurations, such as the various configurations for the microelectronic device package 400 previously described with reference to FIGS. 4, 6B, and 7B, can also be modified in accordance with the various modifications to the microelectronic device package 100 described hereinbelow with reference to FIGS. 8 through 10.

FIG. 8 illustrates an alternate configuration for the microelectronic device package 100, wherein the die stack 106 is formed from multiple dies 806 that are substantially laterally aligned with vertically neighboring dies 806 in the die stack 106. The die stack 106 also includes an insulative film 802 positioned between each adjacent die 806 of the die stack 106. The insulative film 802 may define a space between each adjacent die 806, which provides a space through which a wire bond 804 may contact a surface of one die 806 of the die stack 106 without contacting an adjacent die 806 of the die stack 106. As illustrated in FIG. 8, the die stack 106 may include wire bonds 804 coupling each die 806 of the die stack 106 to a first conductive pad 110. The insulative film 802 may substantially encapsulate the wire bonds 804, such that the wire bonds 804 do not inadvertently contact an adjacent die 806 of the die stack 106. As described above, in some embodiments the conductive pad 110 on both sides of the microelectronic device package 100 may be ground pads 114, which may each be coupled together through the substrate 108.

FIG. 9 illustrates an alternate configuration for the microelectronic device package 100, where the die stack 106 is formed from multiple dies 906 that are substantially laterally aligned with vertically neighboring dies 906 in the die stack 106. The die stack 106 also includes a spacer 904 positioned between each adjacent die 906 of the die stack 106. The spacer 904 may be formed from an insulative material and may define a space between each adjacent die 906, which provides a space through which a wire bond 902 may contact a surface of one die 906 of the die stack 106 without contacting an adjacent die 906 of the die stack 106. As illustrated in FIG. 9, the die stack 106 may include wire bonds 902 coupling each die 906 of the die stack 106 to a first conductive pad 110. As described above, in some embodiments the conductive pad 110 on both sides of the microelectronic device package 100 may be ground pads 114, which may each be coupled together through the substrate 108.

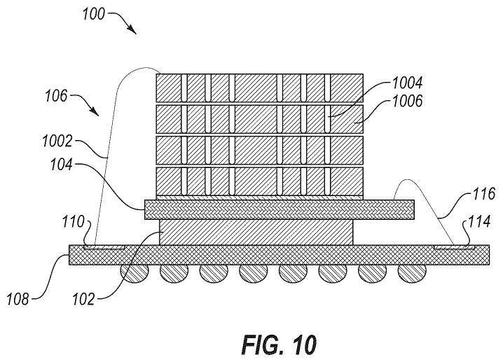

FIG. 10 illustrates an alternate configuration for the microelectronic device package 100, where the die stack 106 is formed from multiple dies 1006 that are substantially laterally aligned with vertically neighboring dies 1006 in the die stack 106. The dies 1006 of the die stack 106 may be coupled together through one or more through silicon vias 1004 (TSVs), extending through each of the dies 1006. The TSVs 1004 may electrically couple the vertically neighboring dies 1006 to one another, similar to the wire bonds 118 of FIG. 1, such that a wire bond 1002 may extend from a top die 1006 of the die stack 106, to operatively couple all of the dies 1006 in the die stack 106 to the conductive pad 110. As described above, in some embodiments the conductive pad 110 on both sides of the microelectronic device package 100 may be ground pads 114, which may each be coupled together through the substrate 108.

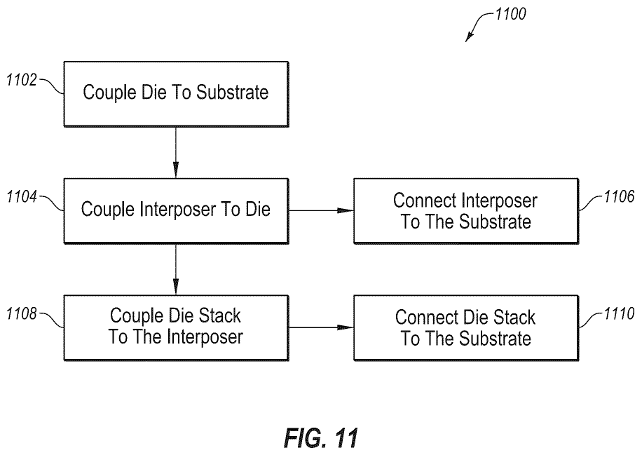

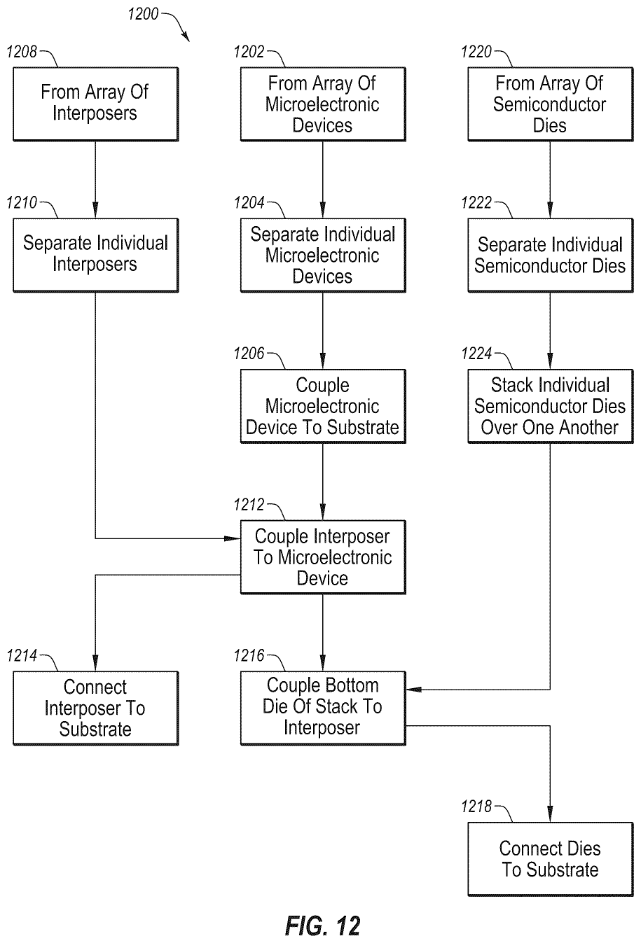

FIG. 11 illustrates a flow chart of a method of assembling 1100 a microelectronic device package (e.g., the microelectronic device packages 100, 400 described above). For the purpose of the method of assembling 1100, the processes of manufacturing the individual parts, such as the semiconductor dies, microelectronic devices, interposers, and so on, are not described. The manufacturing processes are described in greater detail below with respect to FIG. 12.

A microelectronic device, such as a semiconductor die, integrated circuit, controller, and so on, may be coupled to a substrate, such as a printed circuit board, in act 1102. The substrate and the microelectronic device may include complementary connection points, such as posts, pins, solder balls, and/or solder pads. The complementary connection points may include electrical connections through the substrate, such as receiving pads, transmitting pads, power pads, and/or ground pads. The different connection points may be operably coupled to different circuits within the substrate that may transmit electrical signals to other components connected to the substrate. In some embodiments, the microelectronic device is further secured to the substrate through additional material, such as a molding compound.

After the microelectronic device is connected to the substrate, an interposer may be coupled to a surface of the microelectronic device in act 1104. The interposer may be coupled to a surface of the microelectronic device on an opposite side of the microelectronic device opposite the substrate. A conductive structure in the interposer may be connected to the surface of the microelectronic device. The connection between the conductive structure and the microelectronic device may be electrically conductive. For example, the conductive structure may be coupled to the surface of the microelectronic device through a solder connection. In another example, the conductive structure of the interposer may be coupled to the surface of the microelectronic device through a conductive adhesive, such as a metal paste and/or a conductive tape.

The conductive structure of the interposer may then be coupled to the substrate in act 1106. As described above, the conductive structure may extend into a top surface of the interposer, as a conductive pad. The conductive pad may be coupled to the substrate through a wire bond coupled between the conductive pad of the interposer and a ground pad of the substrate. In other embodiments, the conductive structure of the interposer is coupled directly to a ground pad on the substrate through a direct attachment point, such as a post extending from the substrate, such that the conductive structure of the interposer may rest against the direct attachment point and be secured thereto through a soldering process or with a conductive adhesive material similar to the attachment between the conductive structure and the microelectronic device. As described above, the electrical connection between the conductive structure of the interposer and the ground pad of the substrate may form an electrical connection between the outer surface of the microelectronic device and the ground pad, which may drain accumulated electrical charges from the outer surface of the microelectronic device.

A die stack, such as a NAND die stack, may be coupled to a top surface of the interposer in act 1108. The die stack may be coupled to an insulative structure of the interposer. The insulative structure may be positioned between the die stack and the conductive structure(s) of the interposer, such that the die stack may be substantially electrically isolated from the conductive structures of the interposer by the insulative structure. The die stack may be secured to the interposer through an adhesive material, such as a die attach film, tape, and/or epoxy, positioned between a bottom surface of a bottom die of the die stack and the insulative structure of the interposer. The adhesive material may be an insulative material, such that the adhesive material may be configured to further electrically isolate the die stack from the conductive structure(s) of the interposer.

The die stack may then be coupled to the substrate in act 1110. The die stack may be coupled to the substrate through wire bond connections between the dies of the die stack and contact pads of the substrate. The contact pads may include ground pads, power pads, transmitting pads, receiving pads, etc. At least one of the wire bonds may extend from a surface of at least one of the dies and a ground pad of the substrate. The grounding wire bond may be configured to drain an accumulated electrical charge from the outer surface of the die stack. Other wire bonds may be configured to transmit or receive signals to/from the die stack. For example, the wire bonds may be coupled to contact pads, which may be operably coupled to transmit or receive pads associated with the microelectronic device, such that the substrate may facilitate the transmission of electrical signals between the die stack and the microelectronic device.

FIG. 12 illustrates a flow chart representative of a method of manufacturing 1200 a microelectronic device package (e.g., the microelectronic device packages 100, 400 described above). One or more (e.g., each) of the components of the final microelectronic device package may be formed individually and then assembled to form the microelectronic device package. Therefore, the different forming processes may operate in parallel and/or do not have any specific order in which they are completed. Once the individual components are formed, they may then be assembled in the process described above in FIG. 8.

Each of the components may be formed in arrays formed on a substrate, such as a semiconductor wafer through build up processes, such as deposition , sputtering, etc., material removal processes, such as etching (e.g., wet etch, dry etch, etc.), lithography (e.g., photolithography, optical lithography, UV lithography, etc.), etc., and filling processes. Once the array of components is formed the array may be separated into individual components through a separation process, such as a dicing process.

An array of microelectronic devices may be formed on a substrate in act 1202. As described above, the microelectronic devices may be a semiconductor die, integrated circuit, controller, etc. The microelectronic devices may be formed by building up layers of dielectric material over a substrate. Portions of the semiconductor material may then be selectively removed. For example, masks may be used to expose some portions to a removal process while protecting other portions from the removal process. In other examples, a material removal process which selectively removes some types of materials while not removing other types of materials, such as due to differences in a material removal rate for the two different types of materials due to different reactivity between the two different types of material and the material removal process. A backfill operation may then be used to fill in regions where material was removed with a conductive material, to form circuitry and/or other components within the microelectronic devices. These processes may be repeated to form multiple stacked structures and circuitry in the different structures of the microelectronic device. In other cases, multiple stacked structures of insulative material may be formed before the array of microelectronic devices is subject to a selective material removal process.

After the array of microelectronic devices is formed, the substrate may be separated into individual dies or microelectronic devices along scribe lines defined between the multiple microelectronic devices in the array in act 1204. The substrate may be separated through dicing processes. For example, the substrate may be separated through mechanical dicing utilizing a grinding or cutting wheel to cut through the substrate along the scribe lines. In another example, the substrate may be separated through a laser dicing process using a laser to melt the substrate along the scribe lines. In another example, the substrate may be separated through stealth dicing by creating a modified or weakened zone along the scribe lines and fracturing the substrate along the scribe lines using the weakened region in the modified zone to guide the fractures.

An array of semiconductor dies may be formed on another substrate, such as a semiconductor wafer in act 1220. The array of semiconductor dies may be formed in a similar fashion as the array of microelectronic devices. For example, the array of semiconductor dies may be formed through one or more material buildup processes, one or more selective material removal processes, and one or more back filling processes. As described above, these processes may alternate to form stacked structures or may be performed in other orders, such as building up multiple insulative structures before selectively removing some of the insulative structures in a subsequent process.

The array of semiconductor dies may then be separated into individual semiconductor dies in act 1222. As described above, the substrate may be separated through dicing processes, such as mechanical dicing processes, laser dicing processes, and/or stealth dicing processes. The individual dies may then be stacked over one another to form a die stack in act 1224. The individual dies may be stacked in a manner that exposes a portion of the top surface of each die on one or more lateral ends of each die. The exposed portion of the top surface of each die may be used to secure a wire bond to each of the semiconductor dies in the stack in a future step. In some cases, the exposed portion of the top surface of each die may be on the same lateral end of each die in the stack, such as a shingle stack or reverse shingle stack as described and illustrated in FIGS. 1, 4, 6A, and 6B. In other embodiments one or more of the dies in the die stack may be offset in an opposite direction such that the portion of the top surface of the associated die may be on an opposite lateral end of the die from an adjacent die in the die stack, such as the examples illustrated in FIGS. 7A and 7B. In other embodiments, the dies in the die stack may be substantially aligned with vertically neighboring dies in the dies stack and may be arranged with spacers, films, or direct contacts (e.g., TSV's) to facilitate connecting the dies in the die stack to the substrate, such as the examples illustrated in FIGS. 8 through 10. Other types or configurations of die stacks may similarly be built without limitation.

An array of interposers may be formed over a substrate in act 1208. The array of interposers may be formed in a similar manner to that described above in acts 1202 and act 1220. In some cases, the array of interposers may be formed by forming a first insulative structure, selectively removing a portion of the first insulative structure, filling in the region where the insulative material of the insulative structure was removed with a conductive material to form the conducting structure. Another insulative structure may then be formed over the first structure. In some cases, additional material removal and back fill processes may be formed on the additional insulative structures. In other cases, the additional insulative structures may be formed as a single insulative structure over the first structure. After the array of interposers is formed, the array may then be separated into individual interposers in act 1210. As described above, the substrate may be separated through dicing processes, such as mechanical dicing processes, laser dicing processes, and/or stealth dicing processes.

A microelectronic device formed as described above may be provided for an assembly process. The microelectronic device may be coupled to a substrate, such as a printed circuit board, in act 1206. The substrate and the microelectronic device may include complementary connection points, such as posts, pins, solder balls, solder pads, etc. The complementary connection points may include electrical connections through the substrate, such as receiving pads, transmitting pads, power pads, ground pads, etc. The different connection points may be operably coupled to different circuits within the substrate that may transmit electrical signals to other components connected to the substrate. In some embodiments, the microelectronic device may be further secured to the substrate through an additional material, such as a molding compound.

After the microelectronic device is connected to the substrate, an interposer formed as described above, may be provided and coupled to a surface of the microelectronic device in act 1212. The interposer may be coupled to a surface of the microelectronic device on a side of the microelectronic device opposite the substrate. The conductive structure in the interposer may be connected to the surface of the microelectronic device. The connection between the conductive structure and the microelectronic device may be electrically conductive. For example, the conductive structure may be coupled to the surface of the microelectronic device through a solder connection or through a conductive adhesive, such as a metal paste, a conductive tape, etc.

The conductive structure of the interposer may then be coupled to the substrate in act 1214. In some embodiments, the conductive structure extends into a top surface of the interposer through the additional insulative structures of the interposer as a conductive pad. The conductive pad may be coupled to the substrate through a wire bond coupled between the conductive pad of the interposer and a ground pad of the substrate. In other embodiments, the conductive structure of the interposer is coupled directly to a ground pad on the substrate through a direct attachment point, such as a post extending from the substrate, such that the conductive structure of the interposer may rest against the direct attachment point and be secured thereto through a soldering process or with a conductive adhesive material similar to the attachment between the conductive structure and the microelectronic device. As described above, the electrical connection between the conductive structure of the interposer and the ground pad of the substrate may form an electrical connection between the outer surface of the microelectronic device and the ground pad, which may drain accumulated electrical charges from the outer surface of the microelectronic device.

A die stack formed as described above, may be provided and coupled to a top surface of the interposer in act 1216. The die stack may be coupled to a top insulative structure of the interposer. The insulative structure may be positioned between the die stack and the conductive structure(s) of the interposer, such that the die stack may be substantially electrically isolated from the conductive structures of the interposer by the insulative structure. The die stack may be secured to the interposer through an adhesive material, such as a die attach film, tape, epoxy, etc., positioned between a bottom surface of a bottom die of the die stack and the insulative structure of the interposer.

The die stack may then be coupled to the substrate in act 1218. The die stack may be coupled to the substrate through wire bond connections between the dies of the die stack and contact pads of the substrate. The contact pads may include ground pads, power pads, transmitting pads, and/or receiving pads. As described above, each die of the die stack may be arranged such that a portion of a top surface of each die is exposed (e.g., not covered or in contact with an adjacent die in the die stack). The wire bonds may be coupled to the exposed portion of each die in the die stack. In some cases, the wire bond may extend between two adjacent dies in the die stack. In other embodiments, the wire bond may extend from the surface of the die to a conductive pad on the substrate. At least one of the wire bonds may extend from a surface of at least one of the dies and a ground pad of the substrate. The grounding wire bond may be configured to drain an accumulated electrical charge from the outer surface of the die stack. Other wire bonds may be configured to transmit or receive signals to/from the die stack. For example, the wire bonds may be coupled to contact pads, which may be operably coupled to transmit or receive pads associated with the microelectronic device, such that the substrate may facilitate the transmission of electrical signals between the die stack and the microelectronic device.

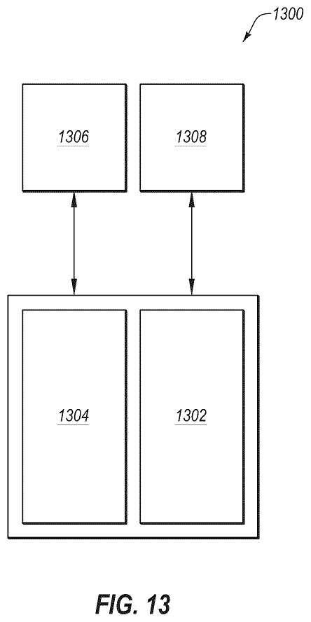

Microelectronic devices (e.g., the microelectronic device packages 100, 400 including the stacked structures of the disclosure) may be included in embodiments of electronic systems of the disclosure. For example, FIG. 13 is a block diagram of an electronic system 1300, in accordance with embodiments of the disclosure. The electronic system 1300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1300 includes at least one memory device 1302. The memory device 1302 may include, for example, an embodiment of a microelectronic device package previously described herein (e.g., the microelectronic device packages 100, 400 previously described with reference to FIGS. 1 through 7B).

The electronic system 1300 may further include at least one electronic signal processor device 1304 (often referred to as a “microprocessor”). The electronic signal processor device 1304 may, optionally, include an embodiment of one or more of a microelectronic device and a microelectronic device structure previously described herein. The electronic system 1300 may further include one or more input devices 1306 for inputting information into the electronic system 1300 by a user, such as, for example, a mouse or other pointing device, a keyboard, a touchpad, a button, or a control panel. The electronic system 1300 may further include one or more output devices 1308 for outputting information (e.g., visual or audio output) to a user such as, for example, a monitor, a display, a printer, an audio output jack, a speaker, etc. In some embodiments, the input device 1306 and the output device 1308 may comprise a single touchscreen device that can be used both to input information to the electronic system 1300 and to output visual information to a user. The input device 1306 and the output device 1308 may communicate electrically with one or more of the memory device 1302 and the electronic signal processor device 1304.

Thus, embodiments of the disclosure include a microelectronic device. The microelectronic device includes a first semiconductor die and a second semiconductor die. The microelectronic device further includes an interposer positioned between the first semiconductor die and the second semiconductor die. The interposer is configured to couple the first semiconductor die to a ground.

Another embodiment of the disclosure includes a microelectronic device package including a microelectronic device coupled to a substrate. The microelectronic device package further includes a stack of semiconductor dies positioned over the microelectronic device. The microelectronic device package also includes an interposer positioned between the microelectronic device and the stack of semiconductor dies. The interposer includes a conductive structure electrically connecting the microelectronic device and a ground circuit of the substrate. The interposer further includes an insulative structure positioned between the conductive structure and the stack of semiconductor dies.

Another embodiment of the disclosure includes a memory device. The memory device includes a substrate including conductive pads, ground pads, and semiconductor material separating the conductive pads and the ground pads. The memory device further includes a first semiconductor die electrically coupled to one or more of the conductive pads of the substrate. The memory device also includes an interposer over the first semiconductor die. The interposer includes a conductive structure electrically coupled to the first semiconductor die. The conductive structure is electrically coupled to at least one ground pad of the ground pads of the substrate through a first wire bond. The memory device further includes a second semiconductor die positioned over the interposer. The second semiconductor die is electrically isolated from the first semiconductor die by an insulative structure of the interposer and the second semiconductor die is electrically coupled to one of the conductive pads of the substrate through a second wire bond.

Other embodiments of the disclosure include an electronic system including an input device, an output device, a processor device operably coupled to the input device and the output device, and a memory device operably coupled to the processor device. The memory device includes an integrated circuit electrically coupled to a substrate. The memory device further includes a stack of semiconductor dies positioned over the integrated circuit. The memory device also includes an interposer positioned between the integrated circuit and the stack of semiconductor dies. The interposer includes a first structure of the interposer including conductive material electrically coupled to the integrated circuit and a second structure of the interposer including insulative material positioned between the conductive material and the stack of semiconductor dies. The memory device further includes a direct attachment coupled between the conductive material of the interposer and a grounding pad in the substrate.

Other embodiments of the disclosure include a method of forming a microelectronic device package. The method includes forming a microelectronic device. The method further includes attaching the microelectronic device to a substrate. The method also includes forming an interposer including a first structure including a conductive material and a second structure including an insulative material. The method further includes coupling the interposer to a surface of the microelectronic device, such that the conductive material of the interposer is electrically coupled to the microelectronic device. The method also includes electrically coupling the conductive material of the interposer to a first ground pad in the substrate. The method further includes forming multiple semiconductor dies. The method also includes assembling a stack of semiconductor dies from the multiple semiconductor dies. The method further includes attaching the stack of semiconductor dies to the interposer, such that the insulative material of the second structure of the interposer is coupled to a bottom semiconductor die of the stack of semiconductor dies. The method also includes electrically coupling the stack of semiconductor dies to a second ground pad in the substrate.

Other embodiments of the disclosure include a method of assembling a microelectronic package. The method includes coupling a microelectronic device to a substrate. The method further includes attaching an interposer to the microelectronic device, the interposer including a conductive pad and insulative material overlying the conductive pad. The method also includes electrically coupling the microelectronic device to the substrate through the interposer. The method further includes attaching a semiconductor die stack to the interposer, the insulative material of the interposer positioned between the semiconductor die stack and the microelectronic device. The method also includes electrically coupling the semiconductor die stack to the substrate through one or more wire bonds.

Embodiments of the disclosure may position an insulative barrier between two stacked microelectronic devices. The insulative barrier may substantially prevent electrical charges built up between the two microelectronic devices from shorting between the devices in an electrostatic discharge. Furthermore, separate grounding elements for the two microelectronic devices may substantially prevent an electrical charge build up. Electrostatic discharge can damage electrical components. Thus, substantially preventing electrostatic discharge and/or preventing an electrical charge from building up between the two microelectronic components may reduce damage to the components, which may result in an extended service life from the associated microelectronic packages and an improved yield by reducing premature failures. Improving service life of the packages and the yield may reduce costs associated with forming the associated microelectronic devices. Reducing the costs of the associated microelectronic devices may similarly result in reduced costs of associated electronic systems and devices.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device package, comprising:
a microelectronic device coupled to a substrate;
a stack of semiconductor dies positioned over the microelectronic device;
an interposer positioned between the microelectronic device and the stack of semiconductor dies, the interposer including:
a conductive structure electrically connecting the microelectronic device and a ground circuit of the substrate; and
an insulative structure positioned between the conductive structure and the stack of semiconductor dies.

2. The microelectronic device package of claim 1, wherein the interposer further comprises a conductive pad extending between an upper surface of the interposer and the conductive structure.

3. The microelectronic device package of claim 2, wherein the conductive pad of the interposer is connected to a ground pad of the substrate through a wire bond.

4. The microelectronic device package of claim 1, wherein the conductive structure of the interposer is coupled to the ground circuit of the substrate through a direct attachment.

5. The microelectronic device package of claim 4, wherein the direct attachment comprises a post extending between the conductive structure of the interposer and the ground circuit of the substrate.

6. The microelectronic device package of claim 1, wherein the conductive structure is electrically connected to the microelectronic device through conductive adhesive.

7. The microelectronic device package of claim 6, wherein the conductive adhesive includes one or more of metal paste, conductive tape, and conductive epoxy.

8. The microelectronic device package of claim 1, wherein the stack of semiconductor dies comprises a stack of memory dies.

9. A memory device, comprising:
a substrate including conductive pads, ground pads, and semiconductor material separating the conductive pads and the ground pads;
a first semiconductor die electrically coupled to one or more of the conductive pads of the substrate;
an interposer over the first semiconductor die and including a conductive structure electrically coupled to the first semiconductor die, the conductive structure electrically coupled to at least one ground pad of the ground pads of the substrate through a first wire bond; and
a second semiconductor die positioned over the interposer and electrically isolated from the first semiconductor die by an insulative structure of the interposer, the second semiconductor die electrically coupled to one of the conductive pads of the substrate through a second wire bond.

10. The memory device of claim 9, wherein the interposer further includes an additional conductive pad overlying and pad electrically coupled to the conductive structure, the additional conductive pad partially defining a top surface of the interposer and the first wire bond is coupled to the conductive structure through the additional conductive pad.

11. The memory device of claim 9, wherein a lateral edge of the interposer extends beyond a lateral end of the second semiconductor die positioned over the interposer.

12. The memory device of claim 11, further comprising one or more additional semiconductor dies stacked over the second semiconductor die, wherein the one or more additional semiconductor dies are partially laterally offset from the second semiconductor die and the lateral edge of the interposer is positioned within a footprint defined by a laterally offset lateral end of the one or more additional semiconductor dies.

13. The memory device of claim 9, wherein the one of the one or more conductive pads of the substrate comprises an additional ground pad.

14. The memory device of claim 13, wherein the additional ground pad is positioned on an opposite side of the first semiconductor die from the at least one ground pad coupled to the conductive structure of the interposer.

15. The memory device of claim 13, wherein the additional ground pad is positioned on a same side of the first semiconductor die as the at least one ground pad coupled to the conductive structure of the interposer.

16. The memory device of claim 13, wherein the additional ground pad includes the at least one ground pad coupled to the conductive structure of the interposer.

17. A method of assembling a microelectronic package, the method comprising:
coupling a microelectronic device to a substrate;
attaching an interposer to the microelectronic device, the interposer comprising a conductive pad and insulative material overlying the conductive pad;
electrically coupling the microelectronic device to the substrate through the interposer;
attaching a semiconductor die stack to the interposer, the insulative material of the interposer positioned between the semiconductor die stack and the microelectronic device; and
electrically coupling the semiconductor die stack to the substrate through one or more wire bonds.

18. The method of claim 17, wherein electrically coupling the microelectronic device to the substrate through the interposer comprises:
coupling the microelectronic device to the conductive pad of the interposer; and
coupling the conductive pad of the interposer to a ground pad of the substrate.

19. The method of claim 18, wherein coupling the conductive pad of the interposer to the ground pad of the substrate comprises coupling the conductive pad to the ground pad through a wire bond extending between the conductive pad and the ground pad.

20. The method of claim 18, wherein coupling the conductive pad of the interposer to the ground pad of the substrate comprises coupling the conductive pad to the ground pad through a conductive structure vertically extending from the ground pad to the conductive pad.
